(19) United States
(12) Patent Application Publication
(10) Pub. No.: US 2010/0048120 A1
(43) Pub. Date: Feb. 25, 2010

(54) ADJUSTABLE AIR VENT DEVICE FOR A COMPUTER HOUSING, AND ASSEMBLY OF A COMPUTER HOUSING AND THE ADJUSTABLE AIR VENT DEVICE

(75) Inventors: Cheng-Hsiang Chuang, Hsichih (TW); Liang Yu, Hsichih (TW); Chia-Ching Lee, Hsichih (TW); Yi-Fen Chen, Hsichih (TW)

Correspondence Address: VEDDER PRICE P.C., 222 N. LASALLE STREET, CHICAGO, IL, 60601, US

(73) Assignee: Wistron Corporation, Hsichih (TW)

(21) Appl. No.: 12/490,456

(22) Filed: Jun. 24, 2009

(30) Foreign Application Priority Data
Aug. 25, 2008 (TW) 097215246

(51) Int. Cl. H05K 7/20

(52) U.S. Cl. 454/184

(57) ABSTRACT

An adjustable air vent device for a computer housing includes a frame and a plurality of slats. The frame extends through an opening formed in the computer housing, and defines an air passage communicating an interior and an exterior of the computer housing. Each of the slats has two opposite lateral edges that are connected pivotally to an inner side of the frame. Due to the pivotal connection of the slats to the frame, direction of flow of air out of the air passage can be changed by adjusting angles of the slats relative to the frame.

### CROSS-REFERENCE TO RELATED APPLICATION

This application claims priority of Taiwanese Application No. 097215246, filed on Aug. 25, 2008.

### BACKGROUND OF THE INVENTION

1. Field of the Invention

The invention relates to an air vent device for a computer housing, more particularly to an adjustable air vent device for a computer housing.

2. Description of the Related Art

With the advance of manufacturing technologies, electronic components, such as hard disk drives, optical disk drives, etc., can be made to have smaller sizes, so that the size of a notebook computer can be even smaller. However, since lightweight and thinness are factors taken into consideration in the design of a notebook computer, the internal components are arranged quite closely. As these electronic components produce heat during operation, the temperature of air around them is relatively high.

Referring to FIG. 1, a housing 11 of a conventional notebook computer device 1 is generally provided with a plurality of heat-dissipating air vents 12 to enable hot air within the housing 11 to be exhausted out of the housing 11 through the heat-dissipating air vents 12.

When a user uses the notebook computer device 1, one of his/her hands will often feel the hot air discharged through the heat-dissipating air vents 12. The hot air is quite comfortable in winter days. But in hot summer days, the hot air may cause discomfort to the user.

In the conventional notebook computer device 1, since the heat-dissipating air vents 12 are fixed, it is not possible to adjust the direction of the hot air exhausted therethrough. As such, the problem associated with discomfort caused to the user remains unresolved.

### SUMMARY OF THE INVENTION

Therefore, an object of the present invention is to provide an adjustable air vent device for a computer housing, which permits adjustment of direction of flow of air exhausted through the air vent device.

Another object of the present invention is to provide an assembly of a computer housing and an adjustable air vent device capable of adjusting direction of flow of air exhausted through the air vent device.

Accordingly, in the adjustable air vent device for a computer housing of the present invention, the computer housing is formed with an opening, and the adjustable air vent device includes a frame and a plurality of slats. The frame extends through the opening, and defines an air passage communicating an interior and an exterior of the computer housing. The slats are spaced apart from each other. Each of the slats has two opposite lateral edges that are connected pivotally to an inner side of the frame.

Preferably, the frame is generally rectangular in shape, and has a pair of first frame walls that are spaced apart from each other and that respectively have inner sides. The lateral edges of each of the slats are connected pivotally and respectively to the inner sides of the first frame walls.

Preferably, the inner sides of the first frame walls of the frame are each provided with a plurality of depressions. The lateral edges of each of the slats are respectively provided with posts that respectively engage a corresponding pair of the depressions in the inner sides of the first frame walls.

Preferably, the first frame walls are spaced apart with one above the other. The frame further has a pair of second frame walls that are connected to the first frame walls and that are spaced apart with one on the left and the other on the right. The second frame walls respectively have outer sides that are respectively formed with first engaging portions. The computer housing has left and right inner lateral edges defining the opening and respectively formed with second engaging portions. The first engaging portions engage the second engaging portions, respectively.

Preferably, the first engaging portions are engaging blocks, and the second engaging portions are engaging grooves.

Preferably, the adjustable air vent device further includes a dust screen extending across the air passage.

Preferably, the dust screen has a screen frame and a screen body connected to the screen frame.

Preferably, one of the second frame walls of the frame is formed with an insert slot for insertion of the dust screen therethrough such that the dust screen extends across the air passage.

Preferably, each of the first frame walls and the other of the second frame walls has an inner side that is provided with a guide groove. The guide groove of each of the first frame walls has two ends that are respectively connected to the insert slot in the one of the second frame walls and the guide groove in the other of the second frame walls. The screen frame is retained in the guide grooves in the first frame walls and the other of the second frame walls.

Preferably, the second frame walls of the frame which are located in the interior of the computer housing are respectively formed with through holes for extension of a heat-dissipating member therethrough.

Preferably, the first frame walls of the frame which are located in the interior of the computer housing are respectively formed with screw holes for extension of screws therethrough so as to secure the frame to the heat-dissipating member.

The assembly of a computer housing and an adjustable air vent device of the present invention includes a computer housing and an adjustable air vent device as described hereinabove.

Preferably, the assembly of a computer housing and an adjustable air vent device further includes a perfume module. The perfume module includes a hood, and a container disposed in the hood and for holding one of essential oil and perfume. The hood defines an air outlet and is provided with an engaging hole. The frame projects outwardly of an outer surface of the computer housing. The hood is attached to the frame by means of the engaging hole so as to be located externally of the computer housing.

The effect of the present invention resides in that, by virtue of the pivotal connection of the slats to the frame, direction of flow of air out of the air passage can be changed by adjusting angles of the slats relative to the frame.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view to illustrate a conventional notebook computer device having heat-dissipating air vents;

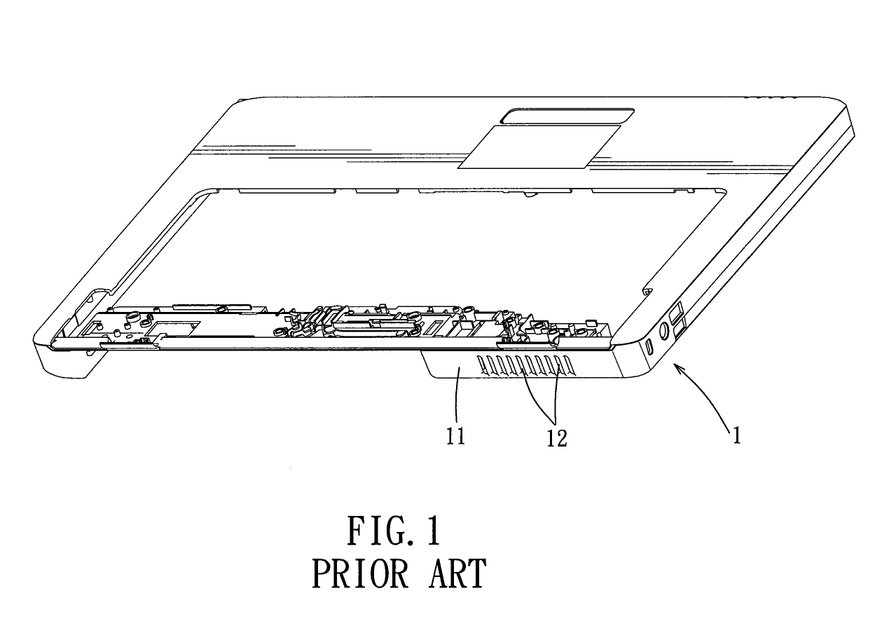

FIG. 2 is a perspective view to illustrate the first preferred embodiment of an assembly of a computer housing and an adjustable air vent device according to the present invention;

FIG. 3 is an exploded perspective view of the first preferred embodiment of FIG. 2;

FIG. 4 is an exploded perspective view to illustrate the first preferred embodiment and a heat-dissipating member;

FIG. 5 is a perspective view to illustrate the second preferred embodiment of an assembly of a computer housing and an adjustable air vent device according to the present invention;

FIG. 6 is an exploded perspective view of the second preferred embodiment;

FIG. 7 is a view similar to FIG. 5, illustrating a different perfume module of the second preferred embodiment;

FIG. 8 is an exploded perspective view to illustrate the third preferred embodiment of an assembly of a computer housing and an adjustable air vent device according to the present invention; and

FIG. 9 is a perspective view to illustrate the fourth preferred embodiment of an assembly of a computer housing and an adjustable air vent device according to the present invention.

### DETAILED DESCRIPTION OF THE PREFERRED EMBODIMENTS

It is particularly noted herein that directional terminologies, such as top, bottom, upper, lower, left, right, front and rear, as used herein are defined in relation to the drawings, and are intended to facilitate description of the present invention rather than limit the scope of the present invention.

Before the present invention is described in greater detail, it should be noted that like elements are denoted by the same reference numerals throughout the disclosure.

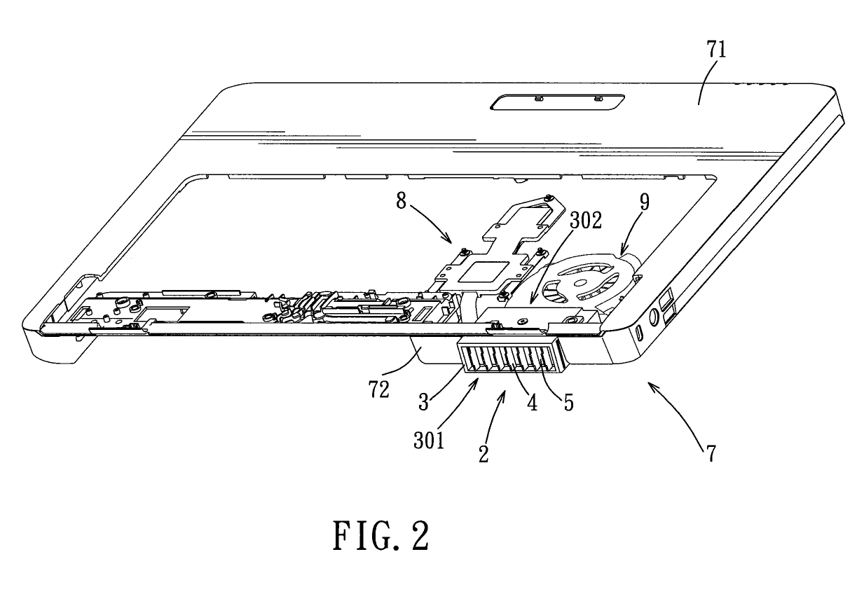

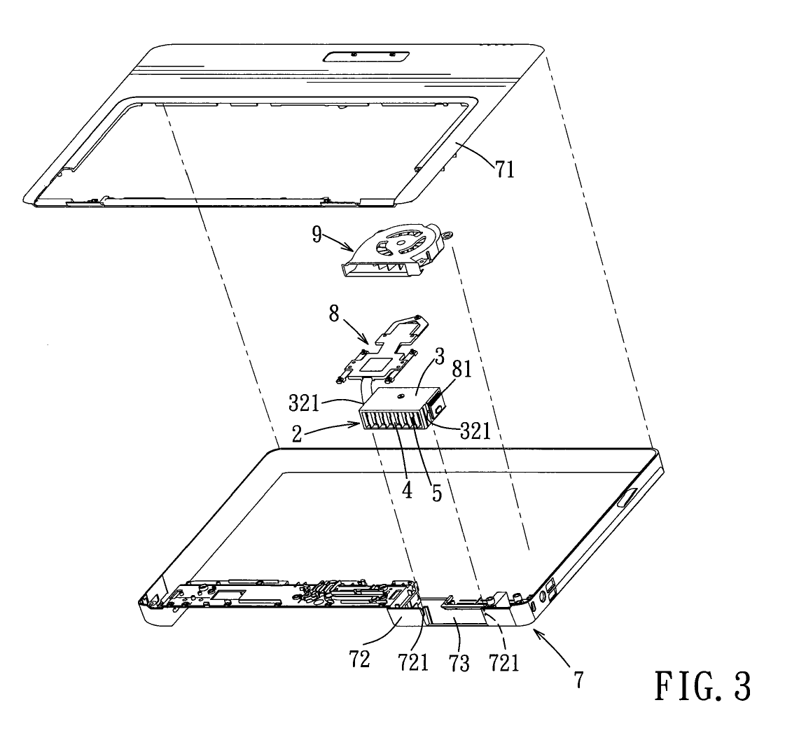

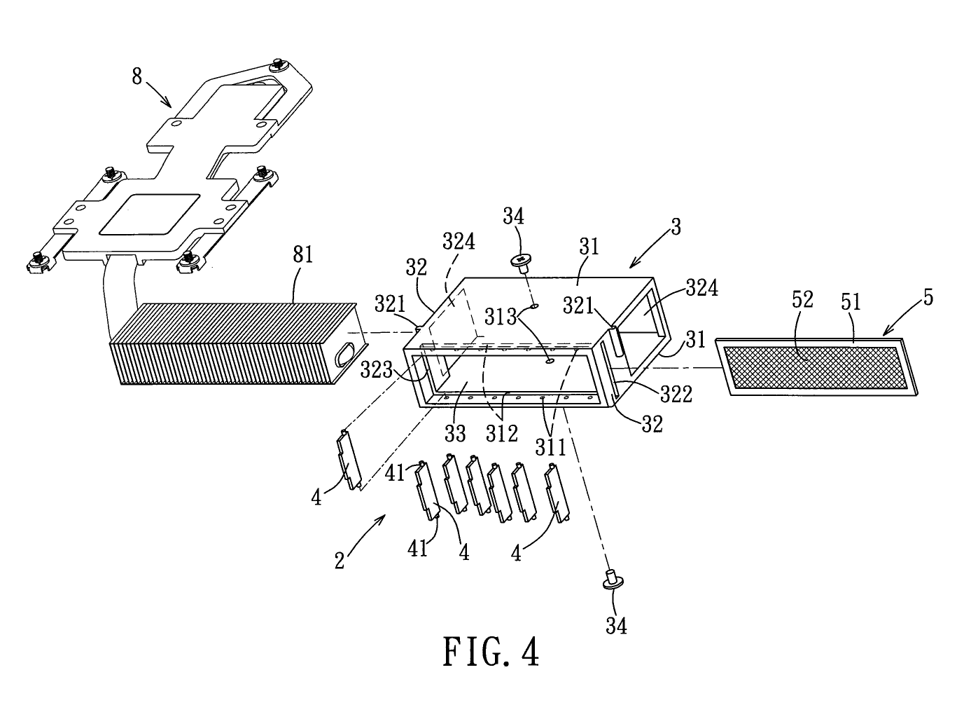

Referring to FIGS. 2, 3 and 4, the first preferred embodiment of an assembly of a computer housing and an adjustable air vent device according to the present invention is shown to include a computer housing 7 and an adjustable air vent device 2. The computer housing 7 includes an upper housing 71 and a lower housing 72. The upper housing 71 and the lower housing 72 cooperatively define a rectangular opening 73. The lower housing 72 has left and right inner lateral edges defining the opening 73 and being respectively formed with second engaging portions 721. In this embodiment, the second engaging portions 721 are engaging grooves that are formed by indenting the inner lateral edges and that extend in a top-bottom direction.

The computer housing 7 of this embodiment has a fan 9 and a heat-dissipating module 8 provided therein. The fan 9 corresponds in position to the opening 73. The heat-dissipating module 8 has a heat-dissipating member 81 located between the fan 9 and the opening 73. The heat-dissipating member 81 referred to herein is a heat sink with heat-dissipating fins.

The adjustable air vent device 2 according to this invention includes a frame 3, a plurality of slats 4, and a dust screen 5. The frame 3 extends through the opening 73 in the computer housing 7, and defines an air passage 33 communicating an interior and an exterior of the computer housing 7. The frame 3 is generally rectangular in shape, and has a pair of first frame walls 31 that are spaced apart with one above the other, and a pair of second frame walls 32 that are connected to the first frame walls 31 and that are spaced apart with one on the left and the other on the right. The first frame walls 31 and the second frame walls 32 surround and define the air passage 33. When the frame 3 is disposed in the housing 7, one end of the frame 3 projects outwardly of the housing 7, while the other end thereof is located within the housing 7. To facilitate the following description, the end of the frame 3 which projects outwardly of the computer housing 7 is defined as a front end 301, whereas the end of the frame 3 which is within the computer housing 7 is defined as a rear end 302. An air current generated by the fan 9 passes through the heat-dissipating member 81 into the frame 3 and out of the computer housing 7 via the front end 301 of the frame 3.

Opposing inner sides of the first frame walls 31 of the frame 3 are each provided with a plurality of depressions 311 and a guide groove 312 that is located rearwardly of the plurality of depressions 311 and that extends in a left-right direction. In addition, the first frame walls 31 are each formed with a screw hole 313.

Each of the second frame walls 32 has an outer side that is formed with a first engaging portion 321 that complements and that corresponds to a respective one of the second engaging portions 721 in shape. In this embodiment, the first engaging portion 321 is an engaging block that extends in the top-bottom direction. Each first engaging portion 321 is used to engage the respective one of the second engaging portions 721 of the lower housing 72. It is noted that the structures of the first and second engaging portions 321, 721 are not limited to those described herein, as long as the first and second engaging portions 321, 721 are complementary in shape and can engage each other.

In addition, one of the second frame walls 32 of the frame 3 is further formed with a narrow insert slot 322 that is located forwardly of the respective first engaging portion 321, that extends in the top-bottom direction, and that is communicated with the air passage 33. The other of the second frame walls 32 of the frame 3 has an inner side that is recessed to form a guide groove 323 that likewise extends in the top-bottom direction. The insert slot 322 and the guide groove 323 correspond to each other in position. Each of the guide grooves 312 in the inner sides of the two first frame walls 31 has two ends that are respectively connected to one end of the guide groove 323 and one end of the insert slot 322 which are formed respectively in the second frame walls 32.

Furthermore, the two second frame walls 32 are respectively formed with through holes 324 that are respectively located rearwardly of the first engaging portions 321 and that are communicated with the air passage 33.

The slats 4 are disposed within the frame 3 proximate to the front end 301 of the frame 3 and are spaced apart from each other. Each of the slats 4 has two opposite lateral edges that are respectively provided with posts 41 projecting therefrom for insertion into a corresponding pair of the depressions 311 in the opposing inner sides of the two first frame walls 31. Thus, each of the slats 4 is pivotably mounted in the frame 3 by means of the lateral edges thereof so as to be pivotable relative to the frame 3.

During assembly of the frame 3 to the computer housing 7, the frame 3 is first placed on the lower housing 72 in the top-bottom direction such that the first engaging portions 321 on the outer sides of the second frame walls 32 of the frame 3 respectively engage the second engaging portions 721 in the inner lateral edges of the lower housing 72 which define the opening 73. The upper housing 71 is then coupled to the lower housing 72 such that the frame 3 extends through the opening 73. In this state, the front end 301 of the frame 3 and the slats 4 are exposed from the computer housing 7, the insert slot 322 in one of the second frame walls 32 is exposed from the computer housing 7, and the through holes 324 in the two second frame walls 32 are within the computer housing 7.

The insert slot 322 in one of the second frame walls 32 is provided for insertion of the dust screen 5 therethrough such that the dust screen 5 extends across the air passage 33. In this embodiment, the dust screen 5 has a screen frame 51, and a screen body 52 connected to the screen frame 51. The dust screen 5 is insertable into the frame 3 through the insert slot 322 in one of the second frame walls 32 of the frame 3, with upper and lower frame edges of the screen frame 51 guided along the guide grooves 312, such that the screen body 52 extends across the air passage 33 and is located rearwardly of the slats 4. When the dust screen 5 is installed in place, the upper and lower frame edges and a lateral edge of the screen frame 51 are respectively retained in the guide grooves 312, 323 in the first frame walls 31 and one of the second frame walls 32, thereby assisting in positioning of the dust screen 5. Since the insert slot 322 is also exposed from the computer housing 7, the user may install or replace the dust screen 5 from the outside of the computer housing 7, thereby facilitating replacement of the dust screen 5.

The through holes 324 formed in the frame 3 and located within the computer housing 7 are provided for extension of the heat-dissipating member 81 therethrough such that the heat-dissipating member 81 can be accommodated within the frame 3. Two screws 34 are inserted respectively into the screw holes 313 in the two first frame walls 31 to abut against upper and lower surfaces of the heat-dissipating member 81, respectively, so as to secure the heat-dissipating member 81 within the frame 3. When the heat-dissipating member 81 is secured within the frame 3, the extension direction of the heat-dissipating fins of the heat-dissipating member 81 are substantially parallel to the direction of flow of the air current within the air passage 33. It is particularly noted that the heat-dissipating member 81 is secured within the frame 3 before the frame 3 is assembled to the computer housing 7. When the air current generated by the fan 9 flows past the heat-dissipating member 81, since the direction of extension of the heat-dissipating fins of the heat-dissipating member 81 is parallel to the direction of flow of the air current in the air passage 33, the air current can flow smoothly past the heat-dissipating fins and absorb the heat around the heat-dissipating fins to thereby form a current of hot air, which flows through the dust screen 5, past the slats 4, and out of the computer housing 7 via the front end 301 of the frame 3. The user can adjust the angles of the slats 4 from the front end 301 of the frame 3 to change the direction of the hot air blowing out through the front end 301 of the frame 3.

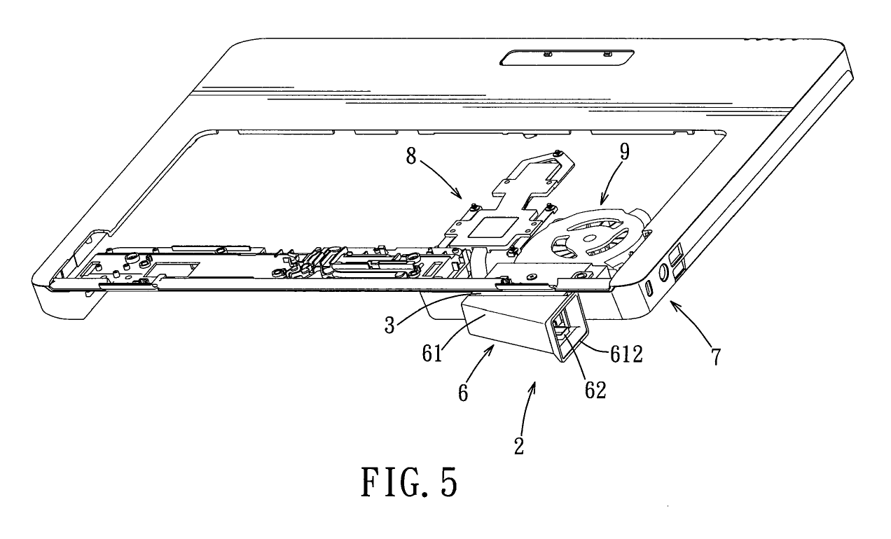

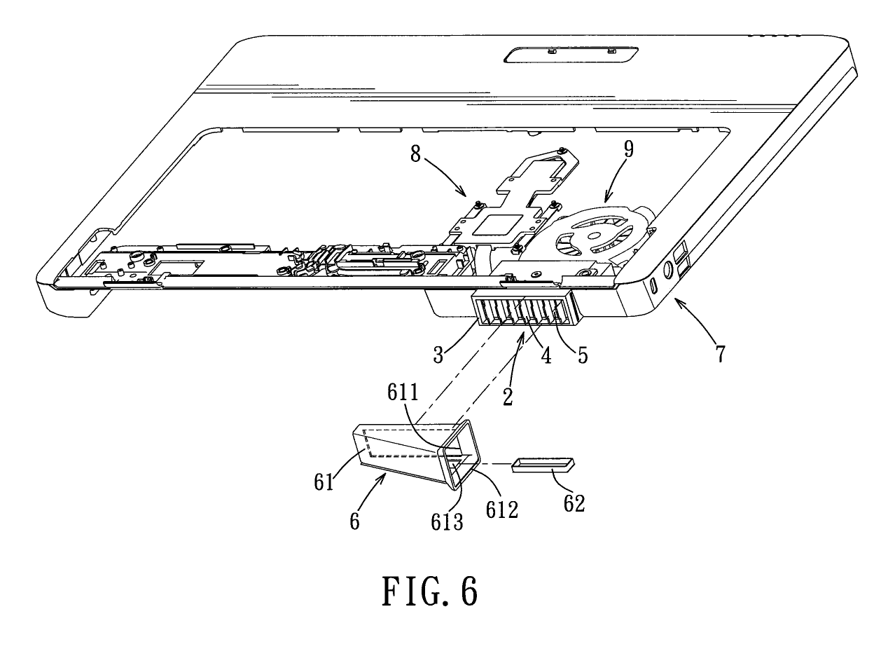

Reference is made to FIGS. 5 and 6, which illustrate the second preferred embodiment of an assembly of a computer housing and an adjustable air vent device according to the present invention. Compared to the first preferred embodiment, the second preferred embodiment further includes a perfume module 6 disposed externally of the computer housing 7 and capable of being coupled to the frame 3, in addition to all of the components of the first preferred embodiment.

The perfume module 6 includes a hood 61 and a container 62 for holding essential oil or perfume. In this embodiment, the hood 61 is shaped like a trumpet and defines an air outlet 612. In addition, the hood 61 has one side provided with an engaging hole 611. In this embodiment, the air outlet 612 is generally perpendicular to the engaging hole 611. The hood 61 is fitted tightly to the front end 301 of the frame 3 by means of the engaging hole 611 so as to be disposed externally of the computer housing 7 with the air outlet 612 opening laterally.

In addition, the hood 61 has a bottom portion provided with a recess 613 in an inner side thereof. The container 62 is disposed in the recess 613.

By attaching the hood 61 to the front end 301 of the frame 3, hot air blowing out of the computer housing 7 through the front end 301 of the frame 3 can enter into the hood 6 and be guided by the contour of the hood 61 to exit laterally through the air outlet 612 of the hood 61. When the hot air flows past the container 62, the essential oil or perfume contained in the container 62 is heated and vaporized, so that the hot air blowing out of the hood 61 carries the aroma of the essential oil or perfume.

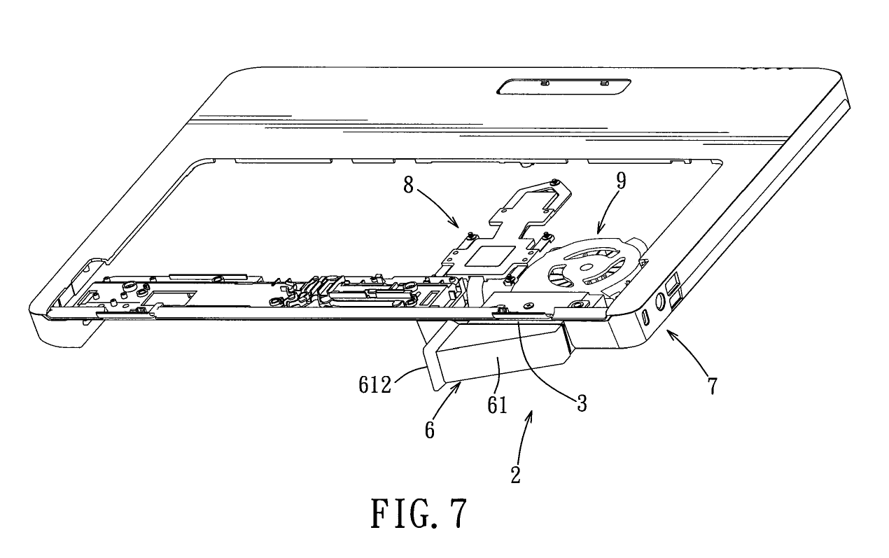

Referring to FIG. 7, the hood 61 can also be configured such that the air outlet 612 is oriented to the left instead of to the right as shown in FIG. 5. Since the underlying principle for such configuration is the same, it will not be discussed further herein.

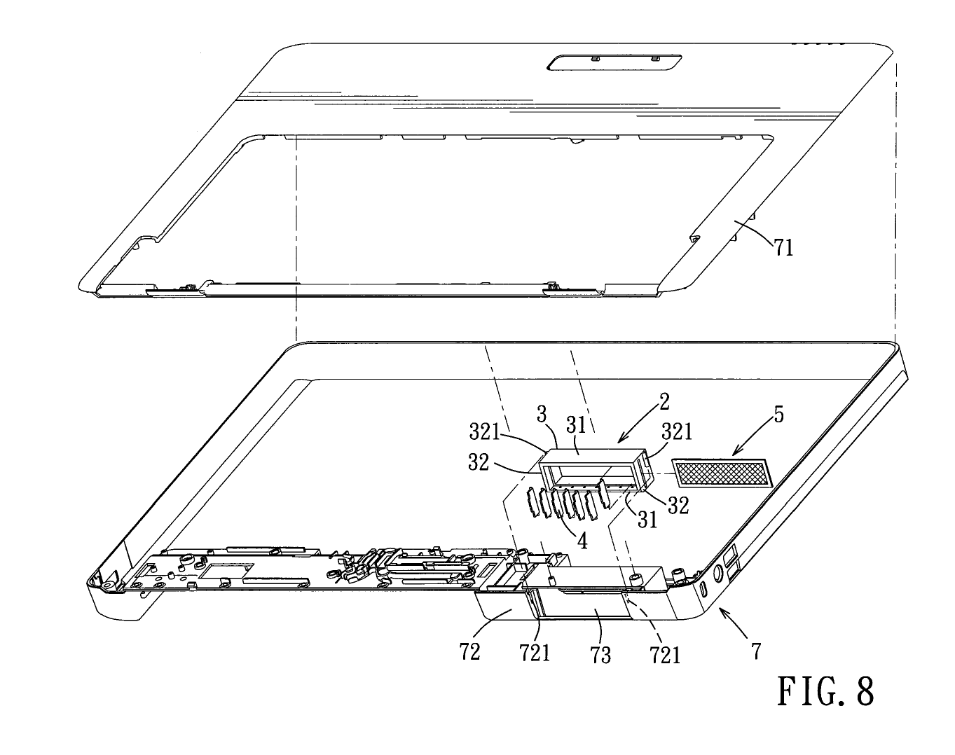

Reference is made to FIG. 8, which illustrates the third preferred embodiment of an assembly of a computer housing and an adjustable air vent device according to the present invention. The third preferred embodiment differs from the first preferred embodiment mainly in the configuration of the frame 3. The following description will focus on the differences with respect to the frame 3.

The third preferred embodiment does not include the heat-dissipating member 81. Therefore, the frame 3 of the adjustable air vent device 2 can be configured to have a shorter dimension in the front-rear direction. Furthermore, the second frame walls 32 do not require the through holes 324 for passage of the heat-dissipating member 81, and the first frame walls 31 do not require the screw holes 313 for securing the heat-dissipating member 81.

Except as stated hereinabove, the frame 3 is substantially the same as that of the first preferred embodiment. The slats 4 and the dust screen 5 of this embodiment are also the same as those of the first preferred embodiment. Therefore, this embodiment can likewise permit adjustment of the direction of hot air exhausted from the computer housing 7 via adjustment of the angles of the slats 4.

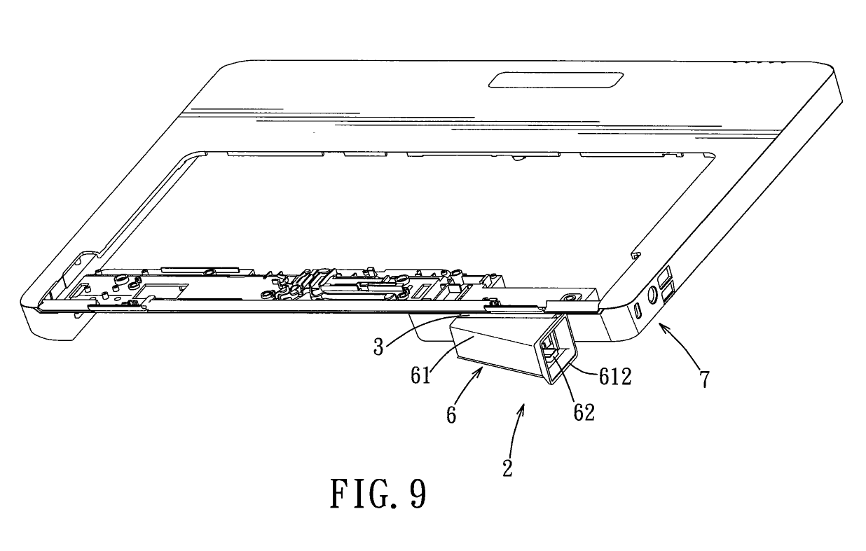

Reference is made to FIG. 9, which illustrates the fourth preferred embodiment of an assembly of a computer housing and an adjustable air vent device according to the present invention. The fourth preferred embodiment includes all of the components of the third preferred embodiment, and further includes a perfume module 6 capable of being coupled to the frame 3 and located externally of the computer housing 7. Since the perfume module 6 of this embodiment is identical to that of the second preferred embodiment, it will not be described in detail herein.

In summary, by configuring the slats 4 of the adjustable air vent device 2 to be adjustable in angle so as to change the direction of hot air blowing out through the frame 3, the user is able to adjust the direction of the hot air blowing out of the computer housing 7 in use, thereby eliminating the problem associated with the discomfort caused to the user by the hot air blowing out of the computer housing 7.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An adjustable air vent device for a computer housing, the computer housing being formed with an opening, said adjustable air vent device comprising:
a frame adapted to extend through the opening, said frame defining an air passage adapted to communicate an interior and an exterior of the computer housing; and
a plurality of slats spaced apart from each other, each of said slats having two opposite lateral edges that are connected pivotally to an inner side of said frame.

2. The adjustable air vent device for a computer housing according to claim 1, wherein said frame is generally rectangular in shape, and has a pair of first frame walls that are spaced apart from each other and that respectively have inner sides, said lateral edges of each of said slats being connected pivotally and respectively to said inner sides of said first frame walls.

3. The adjustable air vent device for a computer housing according to claim 2, wherein said inner sides of said first frame walls of said frame are each provided with a plurality of depressions, said lateral edges of each of said slats being respectively provided with posts that respectively engage a corresponding pair of said depressions in said inner sides of said first frame walls.

4. The adjustable air vent device for a computer housing according to claim 3, wherein said first frame walls are spaced apart with one above the other, said frame further having a pair of second frame walls that are connected to said first frame walls and that are spaced apart with one on the left and the other on the right, said second frame walls respectively having outer sides that are respectively formed with first engaging portions, the computer housing having left and right inner lateral edges defining the opening and respectively formed with second engaging portions, said first engaging portions being adapted to engage the second engaging portions.

5. The adjustable air vent device for a computer housing according to claim 4, further comprising a dust screen extending across said air passage.

6. The adjustable air vent device for a computer housing according to claim 5, wherein one of said second frame walls of said frame is formed with an insert slot for insertion of said dust screen therethrough such that said dust screen extends across said air passage.

7. The adjustable air vent device for a computer housing according to claim 6, wherein each of said first frame walls and the other of said second frame walls has an inner side that is provided with a guide groove, said guide groove of each of said first frame walls having two ends that are respectively connected to said insert slot in said one of said second frame walls and said guide groove in said other of said second frame walls, said screen frame being retained in said guide grooves in said first frame walls and said other of said second frame walls.

8. The adjustable air vent device for a computer housing according to claim 4, wherein said second frame walls of said frame which are located in the interior of the computer housing are respectively formed with through holes adapted for extension of a heat-dissipating member therethrough.

9. The adjustable air vent device for a computer housing according to claim 8, wherein said first frame walls of said frame which are located in the interior of the computer housing are respectively formed with screw holes for extension of screws therethrough so as to permit securing of said frame to the heat-dissipating member.

10. An assembly of a computer housing and an adjustable air vent device, comprising:
a computer housing formed with an opening; and
an adjustable air vent device including
a frame extending through said opening, said frame defining an air passage communicating an interior and an exterior of said computer housing, and
a plurality of slats spaced apart from each other, each of said slats having two opposite lateral edges that are connected pivotally to an inner side of said frame.

11. The assembly of a computer housing and an adjustable air vent device according to claim 10, wherein said frame is generally rectangular in shape, and has a pair of first frame walls that are spaced apart from each other and that respectively have inner sides, said lateral edges of each of said slats being connected pivotally and respectively to said inner sides of said first frame walls.

12. The assembly of a computer housing and an adjustable air vent device according to claim 11, wherein said inner sides of said first frame walls of said frame are each provided with a plurality of depressions, said lateral edges of each of said slats being respectively provided with posts that respectively engage a corresponding pair of said depressions in said inner sides of said first frame walls.

13. The assembly of a computer housing and an adjustable air vent device according to claim 12, wherein said first frame walls are spaced apart with one above the other, said frame further having a pair of second frame walls that are connected to said first frame walls and that are spaced apart with one on the left and the other on the right, said second frame walls respectively having outer sides that are respectively formed with first engaging portions, said computer housing having left and right inner lateral edges defining said opening and respectively formed with second engaging portions for engaging said first engaging portions.

14. The assembly of a computer housing and an adjustable air vent device according to claim 13, wherein said computer housing includes an upper housing and a lower housing, said upper and lower housings cooperatively define said opening, said second engaging portions being located at said lower housing.

15. The assembly of a computer housing and an adjustable air vent device according to claim 14, wherein said first and second engaging portions extend in a top-bottom direction such that said frame is brought to engage said lower housing in the top-bottom direction.

16. The assembly of a computer housing and an adjustable air vent device according to claim 13, wherein said adjustable air vent device further includes a dust screen extending across said air passage.

17. The assembly of a computer housing and an adjustable air vent device according to claim 16, wherein said frame projects outwardly of an outer surface of said computer housing, and said one of said second frame walls of said frame is formed with an insert slot for insertion of said dust screen therethrough such that said dust screen extends across said air passage.

18. The assembly of a computer housing and an adjustable air vent device according to claim 17, wherein each of said first frame walls and the other of said second frame walls has an inner side that is provided with a guide groove, said guide groove of each of said first frame walls having two ends that are respectively connected to said insert slot in said one of said second frame walls and said guide groove in said other of said second frame walls, said screen frame being retained in said guide grooves in said first frame walls and said other of said second frame walls.

19. The assembly of a computer housing and an adjustable air vent device according to claim 13, wherein said second frame walls of said frame which are located in the interior of said computer housing are respectively formed with through holes adapted for extension of a heat-dissipating member therethrough.

20. The assembly of a computer housing and an adjustable air vent device according to claim 19, wherein said first frame walls of said frame which are located in the interior of said computer housing are respectively formed with screw holes for extension of screws therethrough so as to permit securing of said frame to the heat-dissipating member.

21. The assembly of a computer housing and an adjustable air vent device according to claim 10, further comprising a perfume module, said perfume module including a hood, and a container disposed in said hood and for holding one of essential oil and perfume, said hood defining an air outlet and being provided with an engaging hole, said frame projecting outwardly of an outer surface of said computer housing, said hood being attached to said frame by means of said engaging hole so as to be located externally of said computer housing.
